(19) United States
(12) Patent Application Publication
(10) Pub. No.: US 2014/0036465 A1
(43) Pub. Date: Feb. 6, 2014

(54) PACKAGING SUBSTRATE, METHOD FOR MANUFACTURING SAME, AND CHIP PACKAGING BODY HAVING SAME

(71) Applicant: ZHEN DING TECHNOLOGY CO., LTD., Tayuan (TW)

(72) Inventors: CHU-CHIN HU, Taoyuan (TW); SHIH-PING HSU, Taoyuan (TW); E-TUNG CHOU, Taoyuan (TW)

(73) Assignee: Zhen Ding Technology Co., Ltd., Tayuan (TW)

(21) Appl. No.: 13/863,400

(22) Filed: Apr. 16, 2013

(30) Foreign Application Priority Data
Aug. 1, 2012 (TW) 101127808

(51) Int. Cl. H05K 1/18; H05K 3/40

(52) U.S. Cl. CPC H05K 1/181; H05K 3/4038
USPC 361/767; 29/852; 174/257

(57) ABSTRACT

A packaging substrate includes a copper foil substrate, a sputtering copper layer, a dielectric layer, a plurality of electrically conductive connection points, and an electrically conductive pattern layer. The sputtering copper layer is formed on the copper foil substrate. The electrically conductive connection points are formed on a surface of the sputtering copper layer, which is away from the copper foil substrate. The dielectric layer is sandwiched between the electrically conductive pattern layer and the sputtering copper layer. A plurality of first blind via are formed in the first dielectric layer. The electrically conductive pattern layer includes a plurality of electrically conductive traces and a plurality of connection pads. Each electrically conductive connection point is electrically connected to the electrically conductive trace by the first blind via.

### BACKGROUND

1. Technical Field

The present disclosure relates to chip packaging technology, and particularly to, a packaging substrate, a method for manufacturing the packaging substrate, and a chip packaging body having the packaging substrate.

2. Description of Related Art

Chip packaging structure may include a packaging substrate and a chip. The PCB is configured to form a connecting pad. Most of the packaging substrates include a plurality of patterned electrically conductive layers, which make the packaging substrate thick.

When the packaging substrate is thinner, there is need to use a rigid supporting plate to support the packaging substrate. In normal, two packaging substrates are packaged with a rigid supporting plate. The rigid supporting plate is sandwiched between the two packaging substrates. In order to separate the two packaging substrates from each other easily, there is a need to use a special copper foil as a connection portion between the supporting substrate and the packaging substrate. The special copper foil is a structure, which has two copper foils and an adhesive layer between the two copper foils. In addition, the two copper foils have different thicknesses. The special copper foil is expensive, and the packaging structure manufactured by using the special copper foil is also expensive. Accordingly, a cost of a chip packaging structure having the packaging substrate is high.

What is needed therefore is a packaging substrate, a method for manufacturing the packaging substrate, and a chip packaging body having the packaging substrate to overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 shows a first copper foil substrate, a first copper foil, a adhesive sheet, a second copper foil, and a second copper foil substrate according to an exemplary embodiment.

FIG. 2 is a schematic, cross-sectional view of a supporting substrate obtaining by laminating the first copper foil substrate, the first copper foil, the adhesive sheet, the second copper foil, and the second copper foil substrate of FIG. 1 onto each other in the above order.

FIG. 3 shows a first sputtering copper layer and a second sputtering copper layer respectively formed on the two surfaces of the supporting substrate of FIG. 2.

FIG. 4 shows first tooling holes defined in the supporting substrate in FIG. 3.

FIG. 5 shows a first photoresist pattern formed on the first sputtering copper layer in FIG. 4, and a second photoresist pattern formed on the second sputtering copper layer in FIG. 4.

FIG. 6 shows a first electrically conductive pattern formed in the first photoresist pattern in FIG. 5, and a second electrically conductive pattern formed in the second photoresist pattern in FIG. 5.

FIG. 7 shows the first photoresist pattern and the second photoresist pattern removed from the supporting substrate in FIG. 6.

FIG. 8 shows a first dielectric layer and a first electrically conductive layer laminated onto the first electrically conductive pattern in FIG. 7, and a second dielectric layer and a second electrically conductive layer laminated onto the second electrically conductive pattern in FIG. 7.

FIG. 9 shows first blind via formed in the first dielectric layer and the first electrically conductive pattern in FIG. 8, and second blind via formed in the second dielectric layer and the second electrically conductive pattern in FIG. 8.

FIG. 10 shows a first electrically conductive pattern layer converted by the first electrically conductive layer in FIG. 9, and a second electrically conductive pattern layer converted by the second electrically conductive layer in FIG. 9.

FIG. 11 shows a first solder mask formed on the first electrically.

FIG. 12 shows the multilayer substrate of FIG. 11 cut.

FIG. 13 shows a first packaging substrate and a second packaging substrate obtained by cutting the multilayer substrate.

FIG. 14 shows a chip packaged on the packaging substrate of FIG. 13.

FIG. 15 shows the first copper substrate removed from the packaging substrate of FIG. 14.

FIG. 16 shows the first sputtering copper layer removed from the packaging substrate of FIG. 15.

FIG. 17 shows a chip packaging body having the packaging substrate.

### DETAILED DESCRIPTION

A method for manufacturing a packaging substrate according to an exemplary embodiment includes the following steps.

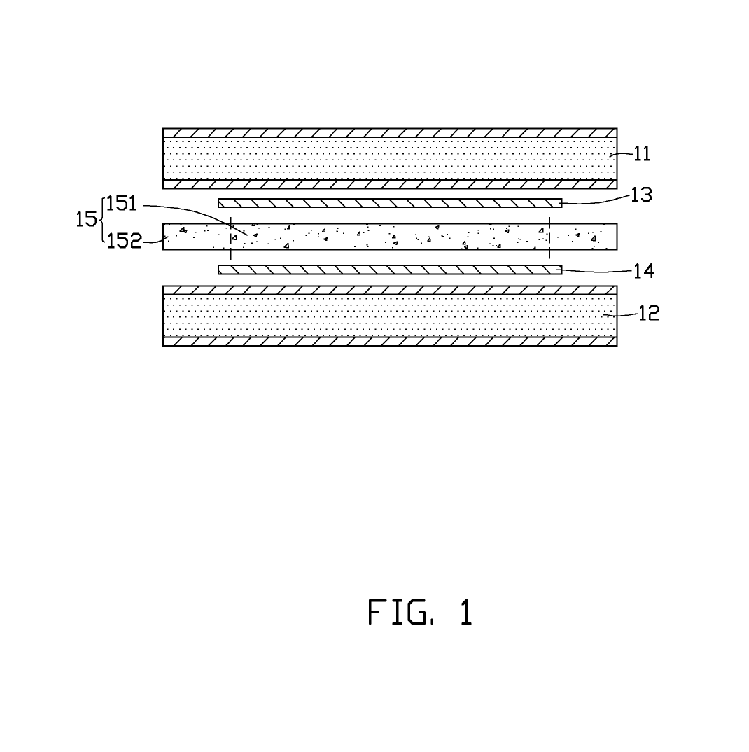

FIG. 1 shows step 1, a first copper foil substrate 11, a second copper foil substrate 12, a first copper foil 13, a second copper foil 14, and an adhesive sheet 15.

Each of the first copper foil substrate 11 and the second copper foil substrate 12 is a double-sided copper clad substrate, and each includes an upper copper foil layer, an lower copper foil layer, and an insulation layer sandwiched between the upper copper foil layer and the lower copper foil layer.

A shape of the first copper foil substrate 11, a shape of the second copper foil substrate 12, and a shape of the adhesive sheet 15 are identical to each other. A size of the first copper foil substrate 11, a size of the second copper foil substrate 12, and a size of the adhesive sheet 15 are identical to each other. A shape of the first copper foil 13,a shape of the second copper foil 14, and the shape of the first copper foil substrate 11 are identical to each other. A size of the first copper foil 13 and a size of the second copper foil 14 are smaller than the size of the first copper foil substrate 11. In detail, an area of a cross-section of the first copper foil substrate 11, an area of a cross-section of the second copper foil substrate 12, and an area of a cross-section of the adhesive sheet 15 are identical to each other; an area of a cross-section of the first copper foil 13 and an area of a cross-section of the second copper foil 14 are identical to each other, and are smaller than an area of a cross-section of the first copper foil substrate 11. The adhesive sheet 15 includes a central area 151 and a peripheral area 152 surrounding the central area 151. The shape of the central area 151 is identical to the shape of the first copper foil 13, and the size of the central area 151 is smaller than the size of the first copper foil 13. That is, an area of a cross-section of the central area 151 is smaller than the area of the cross-section of the first copper foil 13.

In the present embodiment, each of the insulation layers of the first copper foil substrate 11 and the second copper foil substrate 12 is made of an epoxy glass cloth laminated board. The adhesive sheet 15 is a prepreg made of an epoxy glass cloth.

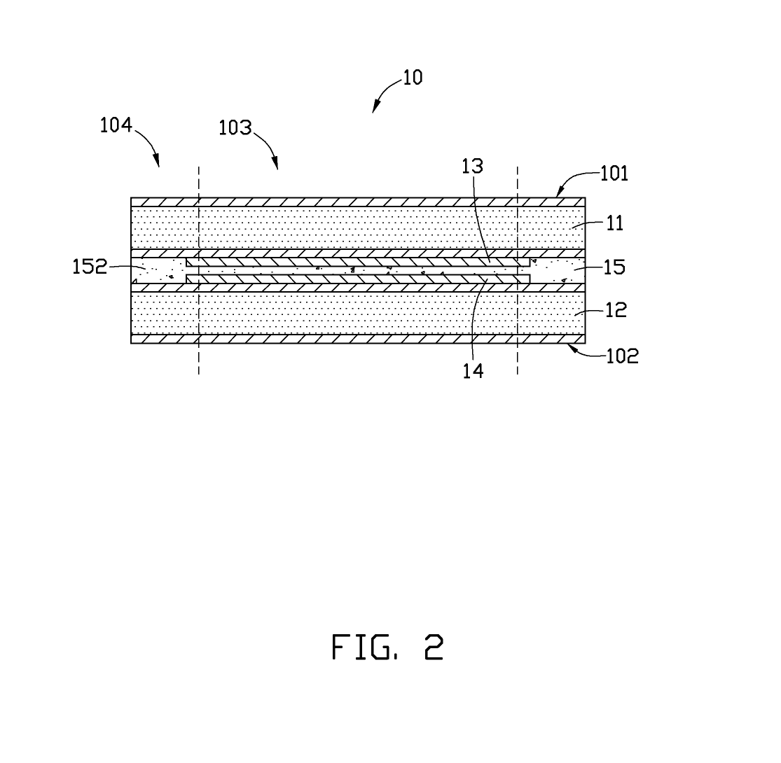

FIG. 2 shows step 2, in which the first copper foil substrate 11, the first copper foil 13, the adhesive sheet 15, the second copper foil 14, and the second copper foil substrate 12 are stacked in the above order, and laminated onto each other by one step lamination, thereby obtaining a supporting substrate 10.

When the first copper foil substrate 11, the first copper foil 13, the adhesive sheet 15, the second copper foil 14, and the second copper foil substrate 12 are stacked, the centers of the first copper foil substrate 11, the first copper foil 13, the adhesive sheet 15, the second copper foil 14, and the second copper foil substrate 12 are aligned with each other. Because the size of the first copper foil 13 and the size of the second copper foil 14 are smaller than the size of the first copper foil substrate 11, the first copper foil 13 and the second copper foil 14 are aligned with the central area 151 of the adhesive sheet 15. When the adhesive sheet 15 is sandwiched between the first copper foil substrate 11 and the second copper foil substrate 12(i.e. lamination), the two sides of the peripheral area 152 are respectively connected to the first copper foil substrate 11 and the second copper foil substrate 12, and the two sides of the central area 151 are respectively connected to the first copper foil 13 and the second copper foil 14, and the central area 151 are not connected to the first copper foil substrate 11 and the second copper foil substrate 12. That is, an orthogonal projection of the first copper foil 13 on the first copper foil substrate 11 and an orthogonal projection of the second copper foil 14 on the first copper foil substrate 11 overlap an orthogonal projection of the central area 151 on the first copper foil substrate 11, such that the first copper foil substrate 11 and the second copper foil substrate 12 are connected to each other only with the adhesive sheet 15.

The supporting substrate 10 includes a first surface 101 and an opposite second surface 102. The first surface 101 is a surface of a copper foil layer of the first copper foil substrate 11. The second surface 102 is a surface of a copper foil layer of the second copper foil substrate 12.

The supporting substrate 10 includes a product area 103 and an unwanted waste area 104 surrounding the product area 103. An area of a cross-section of the product area 103 taken in a plane parallel with the first surface 101 is smaller than an area of a cross-section of the first copper foil 13 taken in a plane parallel with the first surface 101. An orthogonal projection of the product area 103 on the surface of the first copper foil substrate 11 is located within an orthogonal projection of the fist copper foil 13 on the surface of the first copper foil substrate 11.

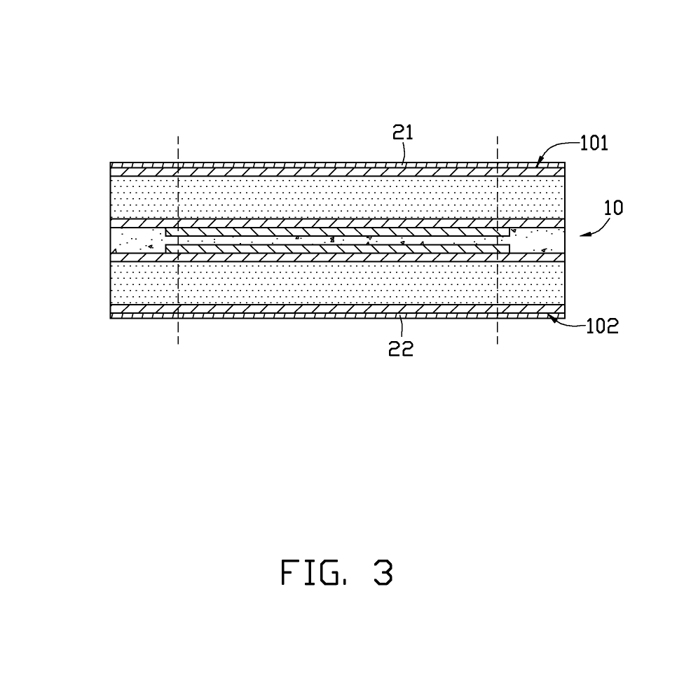

FIG. 3 shows step 3, in which a first sputtering copper layer 21 is formed on the first surface 101, and a second sputtering copper layer 22 is formed on the second surface 102.

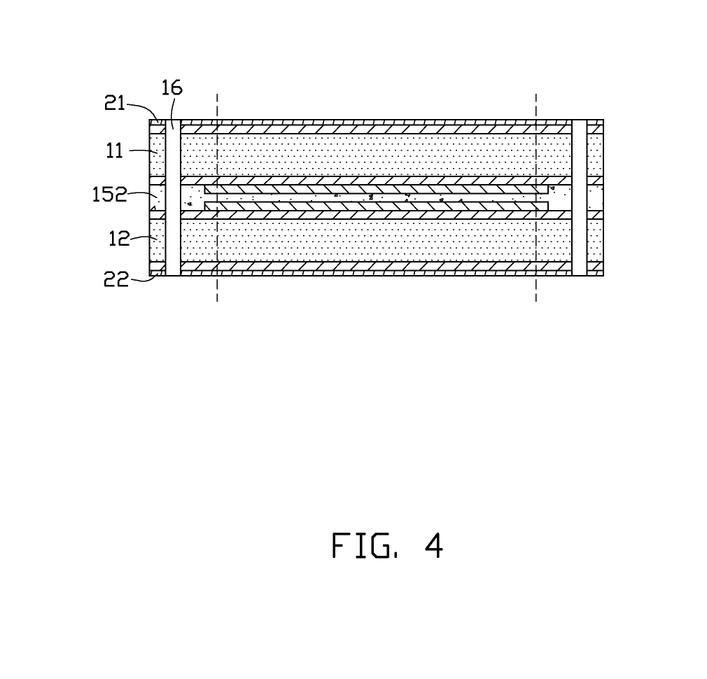

In the present embodiment, a thickness of each of the first sputtering copper layer 21 and the second sputtering copper layer 22 is smaller than 1 micrometer. In the embodiment, the thickness of each of the first sputtering copper layer 21 and the second sputtering copper layer 22 is in a range from 0.1 micrometers to 1 micrometer. Because the first sputtering copper layer 21 and the second sputtering copper layer 22 are formed by sputtering, the first sputtering copper layer 21 and the second sputtering copper layer 22 have a better electroplating performance and a better strippable performance. FIG. 4 shows that in the present embodiment, after forming the first sputtering copper layer 21 and the second sputtering copper layer 22, the method may include a step of defining a plurality of first tooling holes 16 in the supporting substrate 10. The position of the first tooling holes 16 spatially correspond to the peripheral area 152. That is, each first tooling hole 16 passes through the peripheral area 152 of the adhesive sheet 15, portions of the first copper foil substrate 11, the first copper foil 13, the second copper foil 14, and the second copper foil substrate 12 spatially corresponding to the peripheral area. The first tooling holes 16 are configured for locating in the following steps.

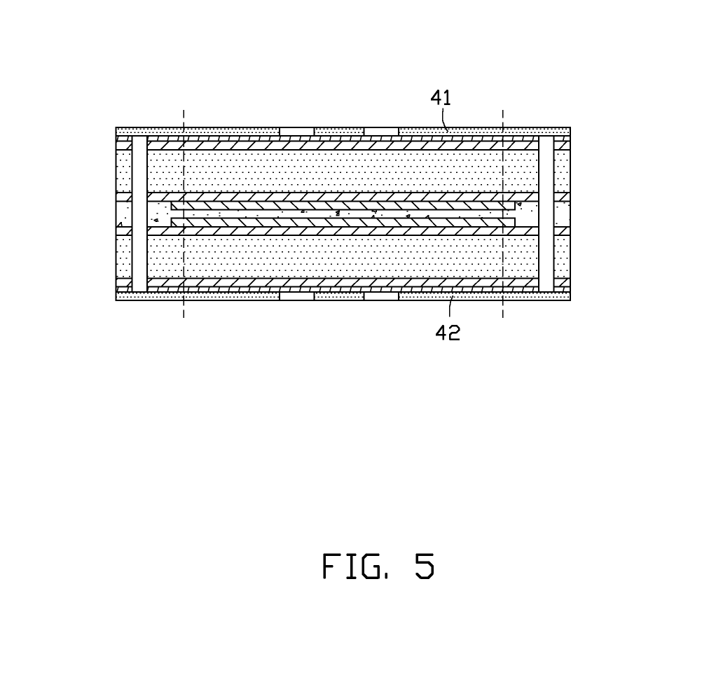

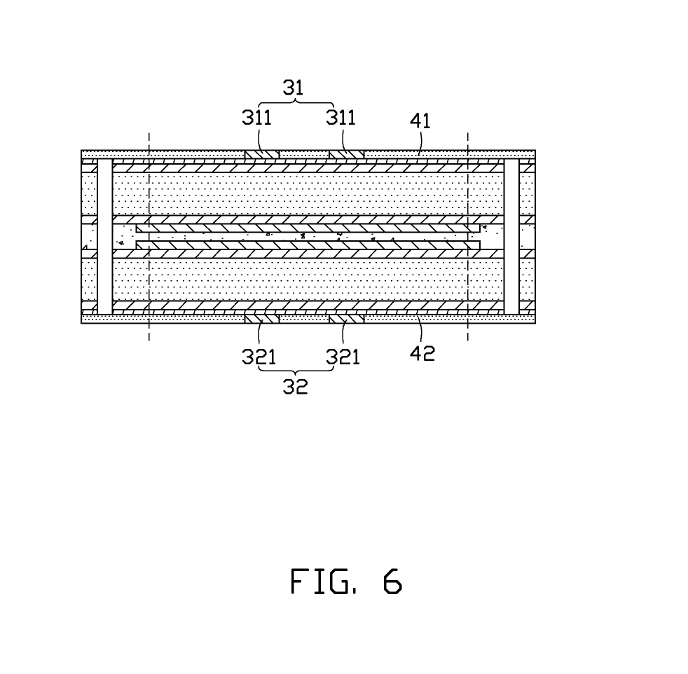

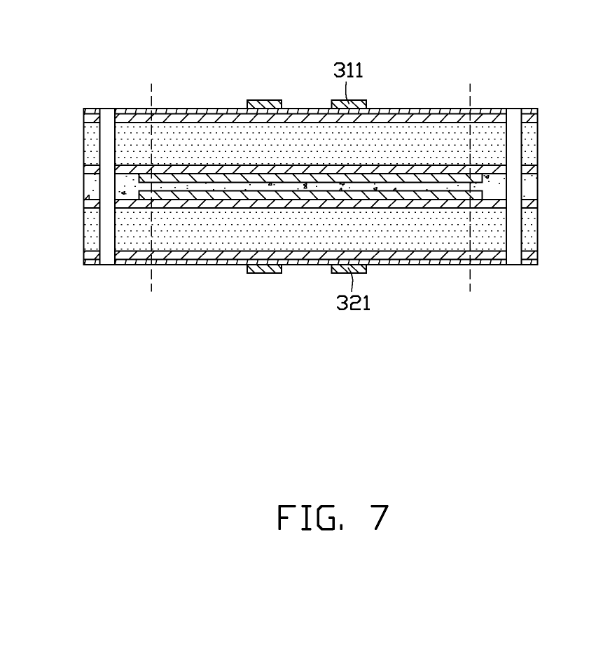

FIGS. 5 to 7 show step 4, in which a first contact pattern 31 is formed on the first sputtering copper layer 21, and a second contact pattern 32 is formed on the second sputtering copper layer 22. The first contact pattern 31 includes a plurality of first electrically conductive connection points 311. The second contact pattern 32 includes a plurality of second electrically conductive connection points 321.

The first electrically conductive connection points 311 and the second electrically conductive connection points 312 may be manufactured by the following method.

First, a first photoresist pattern 41 is formed on the first puttering copper layer 21, and a second photoresist pattern 42 is formed on the second sputtering copper layer 22. In detail, two photoresist layers are respectively formed on the first sputtering copper layer 21 and the second sputtering copper layer 22 by adhering dry films or printing liquid photoimageable resist ink; then, the two photoresist layers are selectively exposed and developed to form the first photoresist pattern 41 and the second photoresist pattern 42, respectively.

Then, the first contact pattern 31 is formed on portions of the first sputtering copper layer 21 exposed from the first photoresist pattern 41 by electroplating, and the second contact pattern 32 is formed on portions of the second sputtering copper layer 22 exposed from the second photoresist pattern 42 by electroplating.

Finally, the first photoresist pattern 41 and the second photoresist pattern 42 are respectively removed from the first sputtering copper layer 21 and the second sputtering copper 22. In the present embodiment, the first photoresist pattern 41 and the second photoresist pattern 42 are both removed by using stripping solution.

The first contact pattern 31 and the second contact pattern 32 are located within the product area 103.

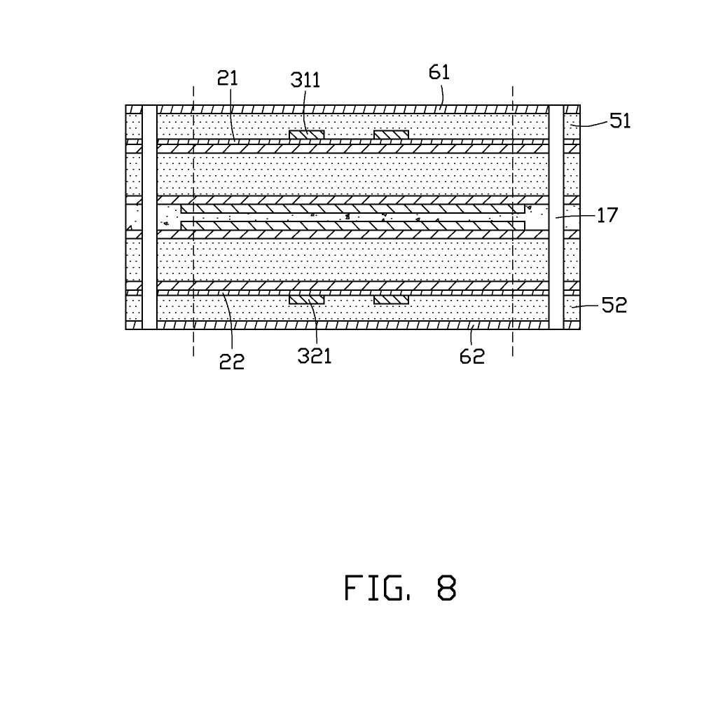

FIG. 8 shows step 5, in which a first dielectric layer 51 and a first electrically conductive layer 61 are laminated over the first sputtering copper layer 21 and the first contact pattern 31. In addition, a second dielectric layer 52 and a second electrically conductive layer 62 are laminated onto the second sputtering copper layer 22 and the second contact pattern 32.

The first dielectric layer 51 and the first electrically conductive layer 61 may be a whole structure. That is, the first dielectric layer 51 and the first electrically conductive layer cooperatively constitute a single-sided copper clad laminate. The second dielectric layer 52 and the second electrically conductive layer 62 may also be a whole structure. That is, the second dielectric layer 61 and the second electrically conductive layer cooperatively constitute a single-sided copper clad laminate.

After step 5, the method may further include a step of defining a plurality of second tooling holes 17 in the first dielectric layer 51, the first electrically conductive layer 61, the supporting substrate 10, the second dielectric layer 52, and the second electrically conductive layer 62. The second tooling holes 17 may be aligned with the first tooling holes 16, and the second tooling holes 17 are configured for locating in the following steps.

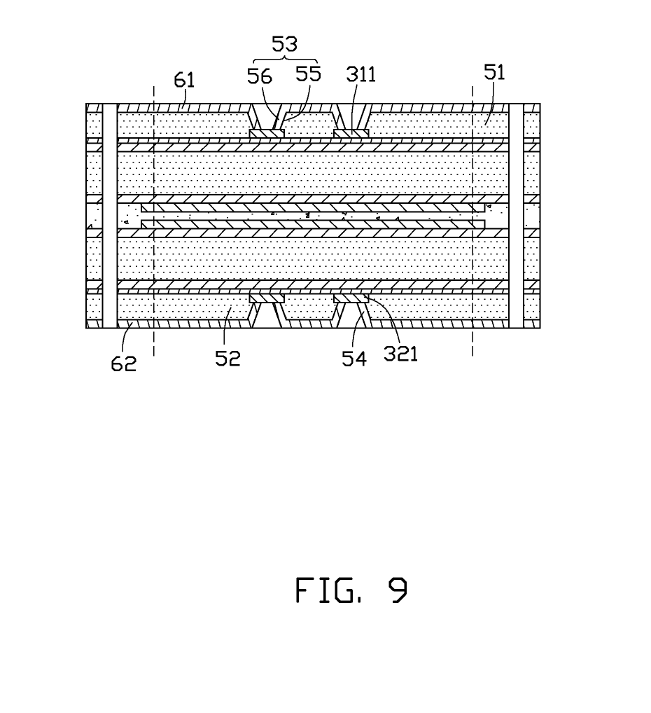

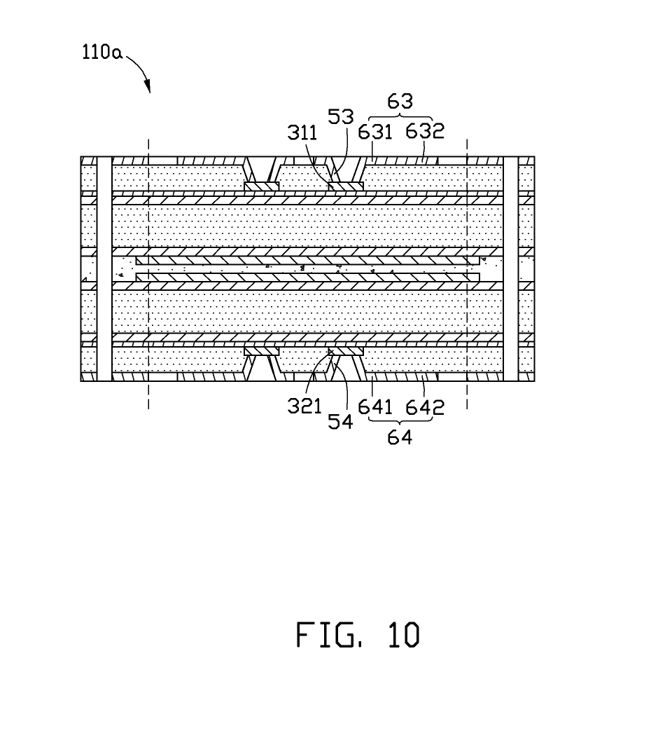

FIGS. 9 and 10 show step 6, in which a plurality of first blind vias 53 are formed in the first electrically conductive layer 61 and the first dielectric layer 51. In addition, a plurality of second blind vias 54 are formed in the second electrically conductive layer 62. The first electrically conductive layer 61 is converted into a first electrically conductive pattern layer 63, the second electrically conductive layer 62 is converted into a second electrically conductive pattern layer 64. The first electrically conductive connection points 311 are electrically connected to the first electrically conductive pattern 63 through the first blind vias 53, and the second electrically conductive connection points 321 are electrically connected to the second electrically conductive pattern 64 through the second blind vias 54. Accordingly, a multilayer substrate 110a is obtained.

The first blind vias 53 may be formed by the following steps.

First, a plurality of first holes 55 are defined in the first electrically conductive layer 61 and the first dielectric layer 51 by a laser beam, and the first contact pattern 31 is exposed in the first holes 55.

Then, an electrically conductive metal layer 56 is formed in the inner surfaces of the first holes 55 and portions of the first contact pattern 31 exposed in the first holes 55, thereby obtaining the first blind vias 53. Electroplating copper or electro-less plating copper may be used to form the electrically conductive metal layer 56. It is understood that the electrically conductive metal layer 56 may be formed on all the first electrically conductive layer 61 to increase the thickness of the first electrically conductive layer 61.

The method for forming the second blind vias 54 may be same as the method for forming the first blind vias 53.

The first electrically conductive pattern 63 and the second electrically conductive pattern 64 may be formed by an image transfer process and an etching process. In the present embodiment, the first electrically conductive pattern 63 includes a plurality of first electrically conductive traces 631 and a plurality of first connection pads 632. The first electrically conductive traces 631 electrically connect the first blind vias 53 and the first connection pads 642. The second electrically conductive pattern layer 64 includes a plurality of first electrically conductive traces 641 and a plurality of second connection pads 642. The second electrically conductive traces 641 electrically connect the second blind vias 54 and the second connection pads 642. That is, each first electrically conductive connection point 311 is electrically connected to one corresponding first connection pad 632 through one corresponding first blind via 53, and one corresponding first electrically conductive trace 631; each second electrically conductive connection point 321 is electrically connected to one corresponding second connection pad 642 through one corresponding second blind via 54, and one corresponding second electrically conductive trace 641.

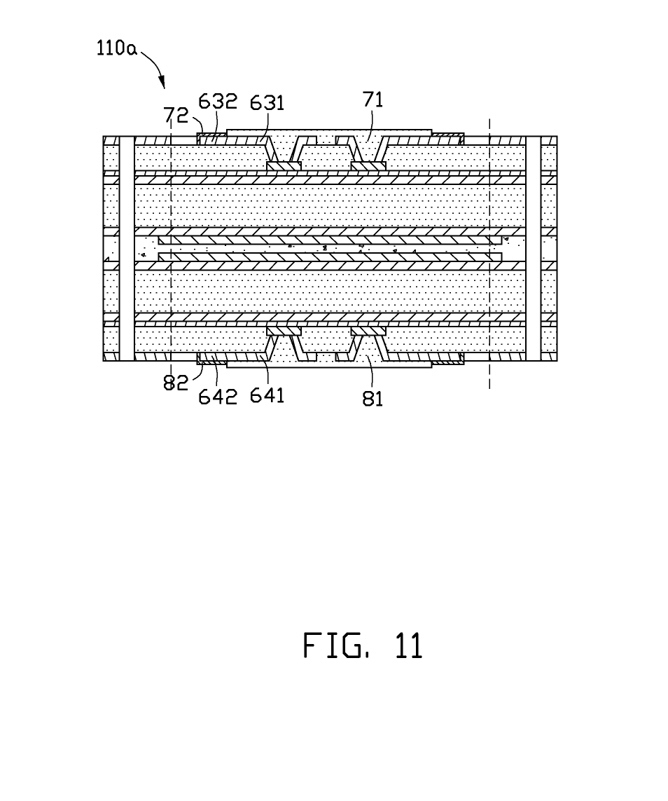

FIG. 11 shows step 7, in which a first solder mask 71 is formed on the first electrically conductive pattern layer 63, such that the first solder mask 71 covers the first electrically conductive traces 631 and portions of the first dielectric layer 51 exposed from the first electrically conductive pattern layer 63, with the first connection pads 632 being exposed. A second solder mask 81 is formed on the the second electrically conductive pattern layer 64, such that the second solder mask 81 covers the second electrically conductive traces 641 and portions of the second dielectric layer 52 exposed from the second electrically conductive pattern layer 64, with the second connection pads 642 being exposed. In addition, a first gold layer 72 and a second gold layer 82 are respectively formed on the first connection pad 632 and the second connection pad 642. The first solder mask 71 and the second solder mask 81 may be formed by printing liquid solder resist ink and baking-curing the printed liquid solder resist ink. The first gold layer 72 and the second gold layer 82 may be formed by a method of plating gold.

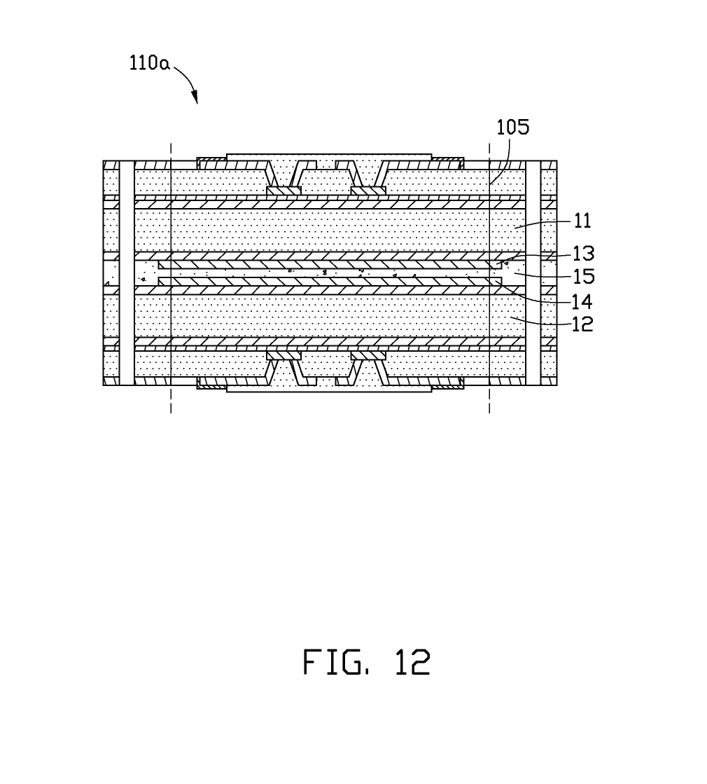

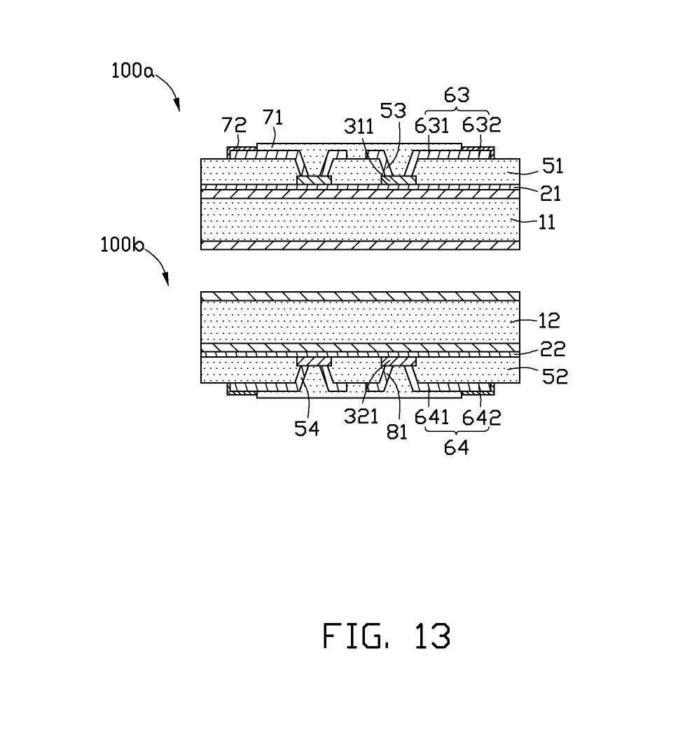

FIGS. 12 and 13 show step 8, in which the multilayer substrate 110a is cut along a boundary between the product area 103 and the unwanted waste area 104 to form a ring-shaped cut 105, such that the product area 103 is separated from the unwanted waste area 104, thereby enabling the first copper foil substrate 11 and the first copper foil 13 in the product area 103 to be naturally separated from each other, and enabling the second copper foil substrate 12 and the second copper foil 14 in the product area 103 to be naturally separated from each other. Then, the naturally separated first copper foil 13, the naturally separated second copper foil 14, and the adhesive sheet 15 are removed off from the product area 103, thereby obtaining a first packaging substrate 100a and a second packaging substrate 100b separated from each other.

In the product area 103, the first copper foil 13 and the second copper foil 14 are directly connected to the adhesive sheet 15, the first copper foil substrate 11 and the second copper foil substrate 12 are not directly connected to the adhesive sheet 15. Accordingly, when the multilayer substrate 110a is cut along a boundary between the product area 103 and the unwanted waste area 104, the first copper foil substrate 11 and the second copper foil substrate 12 are separated from the adhesive sheet 15, such that a separate between the first packaging substrate 100a and second packaging substrate 100b can be obtained.

If there is no first copper foil 13 and the second copper foil 14 between the first copper foil substrate 11 and the second copper foil substrate 12, the first copper foil substrate 11 and the second copper foil substrate 12 may be separated from each other by cutting the adhesive sheet 15, thereby obtaining a separate between the first packaging substrate 100a and second packaging substrate 100b.

FIG. 13 shows that the first packaging substrate 100a is identical to the second packaging substrate 100b. The first packaging substrate 100a includes the first copper foil substrate 11, the first sputtering copper layer 21, the first dielectric layer 51 and the first electrically conductive pattern layer 63, which are arranged in the described order. The first electrically conductive pattern layer 63 includes the first electrically conductive traces 631 and the first connection pads 632. The first electrically conductive connection points 311 are formed on the first sputtering copper layer 21. The first blind vias 53 are formed in the first dielectric layer 51. Each first electrically conductive connection point 311 is electrically connected to the first electrically conductive trace 631 through the first blind via 53. The first solder mask 71 is formed on the first electrically conductive traces 631 and portions of the first dielectric layer 51 exposed from the first electrically conductive traces 631, with the first connection pads 632 being exposed. The first gold layer 72 is formed on the first connection pad 632.

The second packaging substrate 100b includes the second copper foil substrate 12, the second sputtering copper layer 22, the second dielectric layer 52 and the second electrically conductive pattern layer 64, which are arranged in the described order. The second electrically conductive pattern layer 64 includes the second electrically conductive traces 641 and the second connection pads 642. The second electrically conductive connection points 321 are formed on the second sputtering copper layer 22. The second blind vias 54 are formed in the second dielectric layer 52. Each second electrically conductive connection point 321 is electrically connected to the second electrically conductive trace 641 thruogh the second blind via 54. The second solder mask 81 is formed on the second electrically conductive traces 641 and portions of the second dielectric layer 52 exposed from the second electrically conductive traces 641, with the second connection pads 642 being exposed. The second gold layer 82 is formed on the second connection pad 642.

A method for manufacturing a chip packaging body 300 includes the following steps.

FIG. 13 shows step 1, in which the first packaging substrate 100a is provided.

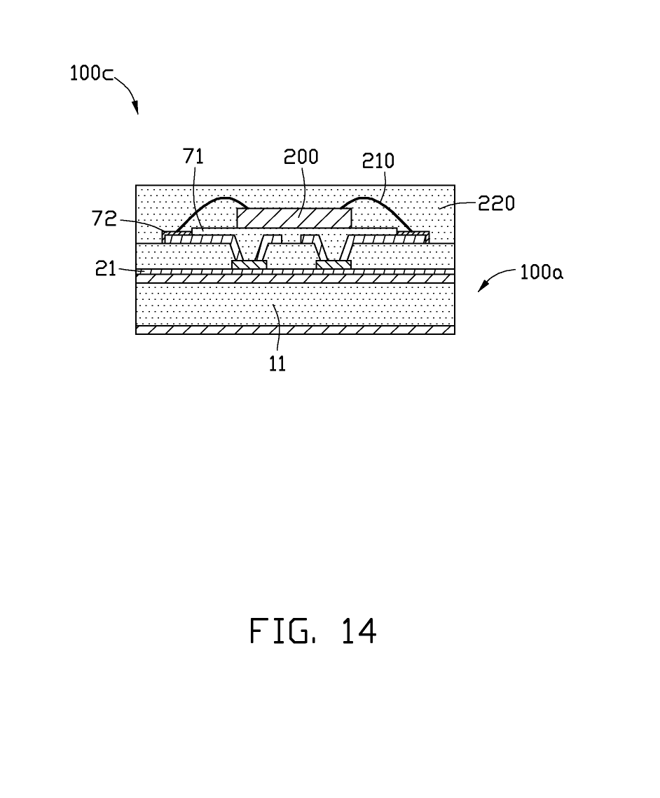

FIG. 14 shows step 2, a chip 200 is packaged on the first packaging substrate 100a, thereby obtaining a chip packaging structure 100c. The method for packaging the chip on the first packaging substrate 100a may include the following steps.

First, the chip 200 is arranged on the first packaging substrate 100a. In the present embodiment, the chip 200 is arranged on the first solder mask 71. When arranging the chip on the first solder mask 71, there may be an adhesive layer positioned between the first solder mask 71 and the chip 200, thereby adhering the chip 200 on the first solder mask 71.

Second, each electronic pad of the chip 200 is electrically connected to one connection pad 632 by a bonding wire 210 by a wire bonding method.

Finally, a packaging material 220 is formed on the chip 200 and the first packaging substrate 100a, such the chip 200, the bonding wires 210, the first packaging substrate 100a, the first solder mask 71, and the first connection pads 632 are wholly covered by the packaging material 220. The packaging material 220 may be thermosetting resin, for example, polyimide resin, epoxy resin, or silicone resin, etc.

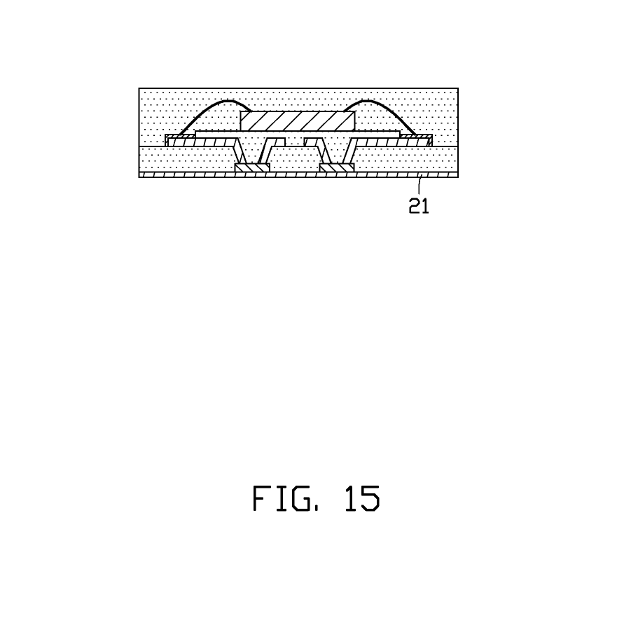

FIG. 15 shows step 3, in which the first copper foil substrate 11 is removed from the chip packaging structure 100c.

Because the thickness of the first sputtering copper layer 21 is smaller, and a bonding force between the first copper foil substrate 11 and the first dielectric layer 51 is also smaller, and the first sputtering copper layer 21 thus has a better strippable performance. Under an external force, the first copper foil substrate 11 is easily separated from the first sputtering copper layer 21, thereby removing the first copper foil substrate 11 from the chip packaging structure 100c.

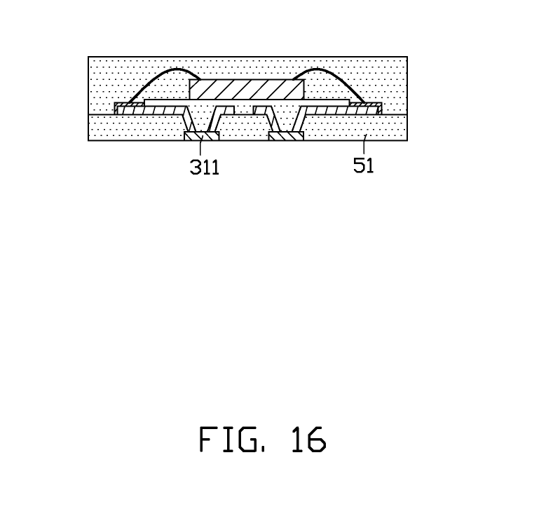

FIG. 16 shows step 4, the first sputtering copper layer 21 is removed from the first dielectric layer 51. In the present embodiment, the first sputtering copper layer 21 is removed from the first dielectric layer 51 by a micro-etching process. That is, a micro-etching solution is reacted with the first sputtering copper layer 21, dissolving and removing the first sputtering copper layer 21 from the first dielectric 51. Accordingly, each first electrically conductive connection point 311 is exposed outside.

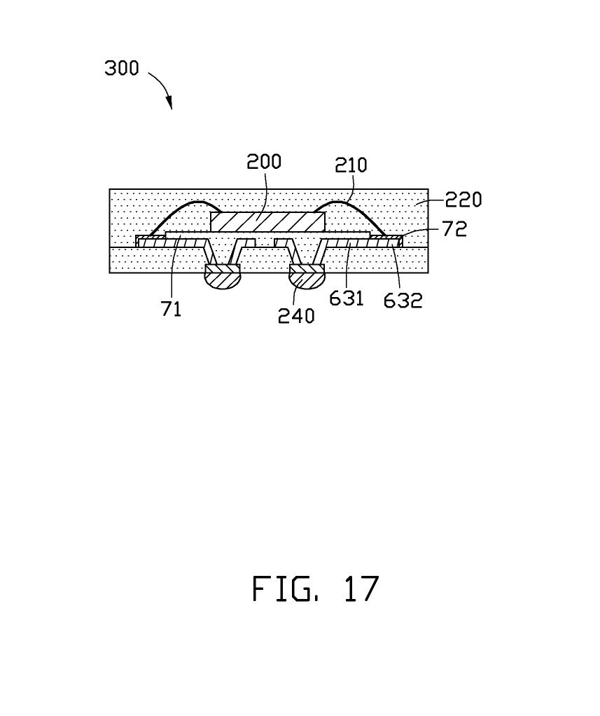

FIG. 17 shows step 5, in which a solder ball 240 is formed on each first electrically conductive connection point 311, thereby obtaining the chip packaging body 300.

The chip packaging body 300 includes a first dielectric layer 51, the first contact pattern 31, the first electrically conductive pattern layer 63, the chip 200, a plurality of bonding wires 210, and the packaging material 220, which are arranged in the described order. The first contacts pattern 31 and the first electrically conductive pattern layer 63 are respectively arranged on the two opposite sides of the first dielectric layer 51. The first contacts pattern 31 includes a plurality of first electrically conductive connection points 311. The first electrically conductive pattern layer 63 includes the first electrically conductive traces 631 and the first connection pads 632. The first blind vias 53 are formed in the first dielectric layer 51. Each first electrically conductive connection point 311 is electrically connected to the first electrically conductive trace 631 through the first blind via 53. The bonding wires 210 electrically connect the chip 200 to the first connection pads 632. The first solder mask 71 is formed on the first electrically conductive traces 631 and portions of the first dielectric layer 51 exposed from the first electrically conductive traces 631, with the first connection pads 632 being exposed. The gold layer 72 is formed on the first connection pad 632. The packaging material 220 contacts with the surface of the first dielectric layer 51 on which the first electrically conductive pattern layer 63 is formed, such that the first electrically conductive pattern layer 63, the chip 200, the bonding wires 210 are wholly packaged in the packaging material 200. The solder ball 240 is formed on the first electrically conductive connection point 311.

In the process of manufacturing the packaging substrate, the sputtering copper layer is formed on the supporting substrate, and the sputtering copper layer has a better electroplating performance and a better strippable performance. Accordingly, in the process of manufacturing the chip packaging body, it is easy to remove the sputtering copper layer (i.e. supporting portion of the packaging substrate) from the packaging substrate. Therefore, no special copper foil structure to form the packaging substrate is needed, and a cost of the packaging substrate and a cost of the chip packaging body having the packaging substrate is lowered.

While certain embodiments have been described and exemplified above, various other embodiments will be apparent from the foregoing disclosure to those skilled in the art. The disclosure is not limited to the particular embodiments described and exemplified but is capable of considerable variation and modification without departure from the scope and spirit of the appended claims.

What is claimed is:

1. A method for manufacturing a packaging substrate, comprising:
providing a first copper foil substrate, an adhesive sheet, and a second copper foil substrate, and sandwiching the adhesive sheet between the first copper foil substrate and the second copper foil substrate, thereby obtaining a supporting substrate, the supporting substrate comprising a first surface and an opposite second surface;
forming a first sputtering copper layer on the first surface, and forming a second sputtering copper layer on the second surface;
forming a plurality of first electrically conductive connection points on the first sputtering copper layer by electroplating, and forming a plurality of second electrically conductive connection points on the second sputtering copper layer by electroplating;
laminating a first dielectric layer and a first electrically conductive layer over the first electrically conductive connection points and the first sputtering copper layer, and laminating a second dielectric layer and a second electrically conductive layer over the second electrically conductive connection points and the second sputtering copper layer;
forming a plurality of first blind vias in the first dielectric layer and the first electrically conductive layer, and converting the first electrically conductive layer into a first electrically conductive pattern layer, the first electrically conductive pattern layer comprising a plurality of first electrically conductive traces and a plurality of first connection pads, each first electrically conductive connection point being electrically connected to one corresponding first connection pad through one corresponding first blind via, and one corresponding first electrically conductive trace, forming a plurality of second blind vias in the second dielectric layer and the second electrically conductive layer, and converting the second electrically conductive layer into a second electrically conductive pattern layer, the second electrically conductive pattern layer comprising a plurality of second electrically conductive traces and a plurality of second connection pads, each second electrically conductive connection point being electrically connected to one corresponding second connection pad through one corresponding second blind via, and one corresponding second electrically conductive trace, thereby obtaining a multilayer substrate;
cutting the multilayer substrate, and removing the adhesive sheet from the first copper foil substrate and the second copper foil substrate, thereby obtaining two separate packaging substrate.

2. The method of claim 1, wherein before cutting the multilayer substrate, the method further comprises the following steps:
forming a first solder mask on the first electrically conductive pattern layer, such that the first solder mask covers the first electrically conductive traces and portions of the first dielectric layer exposed from the first electrically conductive pattern layer, with the first connection pads being exposed; and
forming a second solder mask on the second electrically conductive pattern layer, such that the second solder mask covers the second electrically conductive traces and portions of the second dielectric layer exposed from the second electrically conductive pattern layer, with the second connection pads being exposed.

3. The method of claim 2, wherein after forming the first solder mask, the method further comprises a step of forming a first gold layer on each first connection pad, after forming the second solder mask, the method further comprises a step of forming a second gold layer on each second connection pad.

4. The method of claim 1, wherein when providing the first copper foil substrate, the adhesive sheet, and the second copper foil substrate, a first copper foil and a second copper foil are provided, an area of a cross-section of the first copper foil substrate, an area of a cross-section of the second copper foil substrate, and an area of a cross-section of the adhesive sheet are identical to each other, an area of a cross-section of the first copper foil and an area of a cross-section of the second copper foil are identical to each other, and are smaller than an area of a cross-section of the first copper foil substrate, the adhesive sheet comprises a central area and a peripheral area surrounding the central area, an area of a cross-section of the central area is smaller than the area of the cross-section of the first copper foil; when the adhesive sheet is sandwiched between the first copper foil substrate and the second copper foil substrate, the first copper foil is sandwiched between the adhesive sheet and the first copper foil substrate, the second copper foil is sandwiched between the adhesive sheet and the second copper foil substrate, the first copper foil and the second copper foil contact the central area of the adhesive sheet, an orthogonal projection of the first copper foil on the first copper foil substrate and an orthogonal projection of the second copper foil on the first copper foil substrate overlap an orthogonal projection of the central area on the first copper foil substrate, such that the first copper foil substrate and the second copper foil substrate are connected to each other only with the adhesive sheet.

5. The method of claim 4, wherein the supporting substrate comprises a product area and an unwanted waste area surrounding the product area, the product area spatially corresponds the central area, and an orthogonal projection of the product area on the first copper foil substrate is located within an orthogonal projection of the first copper foil on the first copper foil substrate, when the multilayer substrate is cut, the multilayer substrate is cut along a boundary between the product area and the waste area, such that the product area is separated from the waste area, thereby enabling the first copper foil substrate and the first copper foil in the product area to be naturally separated from each other, and enabling the second copper foil substrate and the second copper foil in the product area to be naturally separated from each other, the naturally separated first copper foil, the naturally separated second copper foil, and the adhesive sheet are removed off from the product area, thereby obtaining two packaging substrates separated from each other.

6. A packaging substrate, comprising a copper foil substrate, a sputtering copper layer, a dielectric layer, a plurality of electrically conductive connection points, and an electrically conductive pattern layer, the sputtering copper layer being formed on the copper foil substrate, the electrically conductive connection points being formed on a surface of the sputtering copper layer which is far away from the copper foil substrate, the dielectric layer being sandwiched between the electrically conductive pattern layer and the sputtering copper layer, a plurality of first blind vias being formed in the first dielectric layer, the electrically conductive pattern layer comprising a plurality of electrically conductive traces and a plurality of connection pads, each electrically conductive connection point being electrically connected to the electrically conductive trace through the first blind via.

7. The packaging substrate of claim 6, further comprising a solder mask, the solder mask covering the electrically conductive traces and the dielectric layer exposed from the electrically conductive traces, with the connection pads being exposed.

8. The packaging substrate of claim 7, further comprising a gold layer formed on the connection pad.

9. The method of claim 6, wherein a thickness of the sputtering copper layer is in a range from 0.1 micrometers to 1 micrometer.

10. A chip packaging chip, comprising a packaging substrate and a chip packaged on the packaging substrate, the packaging substrate comprising a copper foil substrate, a sputtering copper layer, a dielectric layer, a plurality of electrically conductive connection points, and an electrically conductive pattern layer, the sputtering copper layer being formed on the copper foil substrate, the electrically conductive connection points being formed on a surface of the sputtering copper layer which is far away from the copper foil substrate, the dielectric layer being sandwiched between the electrically conductive pattern layer and the sputtering copper layer, a plurality of first blind vias being formed in the first dielectric layer, the electrically conductive pattern layer comprising a plurality of electrically conductive traces and a plurality of connection pads, each electrically conductive connection point being electrically connected to the electrically conductive trace through the first blind via, the chip being electrically connected to the connection pads.

11. The chip packaging body of claim 10, further comprising a solder mask, the solder mask covering the electrically conductive traces and portions of the dielectric layer exposed from the electrically conductive traces, with the connection pads being exposed.

12. The chip packaging body of claim 11, further comprising a plurality of gold layers, one of the gold layers being formed on the corresponding connection pad, the chip being electrically connected to the connection pads through the gold layers.

13. The chip packaging body of claim 10, wherein a thickness of the sputtering copper layer is in a range from 0.1 micrometers to 1 micrometer.
